(19) United States
(12) Patent Application Publication
(10) Pub. No.: US 2018/0209034 A1
(43) Pub. Date: Jul. 26, 2018

(54) TARGET MATERIAL

(71) Applicant: Hitachi Metals, Ltd., Tokyo (JP)

(72) Inventors: Masashi KAMINADA, Shimane (JP); Kazuya SAITOH, Shimane (JP); Yuu TAMADA, Shimane (JP); Hide UENO, Shimane (JP)

(73) Assignee: Hitachi Metals, Ltd., Tokyo (JP)

(21) Appl. No.: 15/745,994

(22) PCT Filed: Jul. 26, 2016
(86) PCT No.: PCT/JP2016/071807

§ 371 Date: Jan. 19, 2018

(30) Foreign Application Priority Data
Jul. 27, 2015 (JP) 2015-147575

(51) Int. Cl. C23C 14/34; C22C 27/04

(52) U.S. Cl. CPC C23C 14/3414; B22F 3/14; C22C 27/04

(57) ABSTRACT

Provided is a target material which suppresses contamination of a gate electrode during sputtering and which is used to form a gate electrode capable of achieving stable TFT characteristics. This target material contains a total of 50 atom % or more of one or more elements (M) selected from among the group consisting of W, Nb, Ta, Ni, Ti and Cr, with the remainder comprising Mo and unavoidable impurities, wherein a content of K, which is one of the unavoidable impurities, is preferably 0.4 to 20.0 ppm by mass and a content of W as the element (M) is preferably 10 to 50 atom %.

### TECHNICAL FIELD

The present invention relates to a target material used in physical vapor deposition technology such as sputtering.

### BACKGROUND ART

For a thin film transistor type liquid crystal display or the like that is a type of flat display device, a polysilicon TFT in which a polysilicon film having high electron mobility is formed on a gate insulating film formed on a gate electrode has recently been adopted. Since fabrication of this polysilicon TFT requires, for instance, a high-temperature process such as high-temperature activation thermal treatment of 450° C. or higher, a material that is excellent in a high temperature characteristic, corrosion resistance, etc. is required such that deformation or fusion does not occur at the gate electrode. A high-fusion-point material such as Mo or a Mo alloy is applied to the material of the gate electrode.

As the gate electrode formed of this high-fusion-point material, for instance, as in Patent Literature 1, a MoW alloy in which W is added to Mo at a rate of not less than 8 atom % and less than 20 atom % is proposed, and a target material for forming this gate electrode is also disclosed. Patent Literature 1 is useful technology in that the gate electrode formed of the MoW alloy disclosed in Patent Literature 1 has more excellent corrosion resistance than a gate electrode formed of pure Mo in addition to the fact that no hillock is formed without the deformation and the fusion with respect to the high-temperature activation thermal treatment of 450° C. or higher.

### CITATION LIST

### Patent Literature

### [Patent Literature 1]

Republished Japanese Translation No. 2012/067030 of the PCT International Publication

### SUMMARY OF INVENTION

### Technical Problem

According to examination of the inventors of the present invention, it was confirmed that, in the polysilicon TFT in which the gate electrode formed using the target material formed of the MoW alloy disclosed in Patent Literature 1 is adopted, stable TFT characteristics could not be sometimes obtained, and for example either a change in threshold voltage of a semiconductor occurred or switching was difficult within a predetermined voltage range.

The inventors confirmed that, when the target material formed of the MoW alloy was disposed inside a chamber of a sputtering system and was sputtered after the inside of the chamber was adjusted to a predetermined degree of vacuum, the inside of the chamber was sometimes contaminated. It was confirmed that, along with a problem with the contamination of the inside of the chamber, K (potassium) was sometimes incorporated into an obtainable film, that is, a gate electrode.

In view of the above problems, an object of the present invention is to provide a target material capable of inhibiting contamination of a film during sputtering and of forming a gate electrode from which stable TFT characteristics are obtained.

### Solution to Problem

The inventors found that, when a target material formed of a Mo alloy is used to form a gate electrode of a polysilicon TFT, a content of K contained in the target material needs to be inhibited within a proper range, which led to the present invention.

That is, a target material of the present invention contains a total of 50 atom % or less of one or two or more elements (M) selected from the group consisting of W, Nb, Ta, Ni, Ti and Cr, with the remainder comprising Mo and unavoidable impurities, wherein a content of K, which is one of the unavoidable impurities, is 0.4 to 20.0 ppm by mass.

The element (M) is preferably W, a content of which is 10 to 50 atom %.

### Advantageous Effects of Invention

With use of the target material of the present invention, it is possible to inhibit contamination of a film during sputtering and form a gate electrode from which stable TFT characteristics are obtained. The present invention is technology useful for fabrication of a flat display device.

### BRIEF DESCRIPTION OF DRAWINGS

FIG. 1 is a schematic view of a thin film transistor (TFT) structure.

FIG. 2 is a relation view between a voltage and a current indicating TFT characteristics in exemplary example 4 of the present invention.

FIG. 3 is a relation view between a voltage and a current indicating TFT characteristics in a comparative example.

### DESCRIPTION OF EMBODIMENTS

The inventors of the present invention confirmed that, when various Mo-based target materials were disposed inside a chamber of a sputtering system and were sputtered after the inside of the chamber was adjusted to a predetermined degree of vacuum, the inside of the chamber was sometimes contaminated, and an obtained film, that is, a gate electrode, was also sometimes contaminated.

The inventors confirmed that, in examining characteristics of a polysilicon TFT in which a gate electrode was formed using various Mo-based target materials, a change in threshold voltage of a semiconductor sometimes occurred, switching was sometimes difficult within a predetermined voltage range, and stable TFT characteristics could not be sometimes obtained. It was confirmed that these problems were induced by a K content contained in the target material.

In a target material of the present invention, a K content contained as one of elements of unavoidable impurities is set to 0.4 to 20.0 ppm by mass. In a case in which the K content contained in the target material is more than 20.0 ppm by mass, when the target material is disposed inside a chamber of a sputtering system and sputtering is performed after the inside of the chamber is adjusted to a predetermined degree of vacuum, K is scattered inside the chamber, and the inside of the chamber is contaminated. As a result, an obtainable gate electrode is also contaminated. The problem of the contamination caused by K also causes a problem that a film formed using another target material thereafter is also contaminated. Further, when the inside of the chamber is contaminated with K, many man-hours are required to clean the inside of the chamber.

When the scattering of K increases during sputtering, a change in amount of K in the gate electrode is increased, and a change in TFT characteristics is also increased. When the K content contained in the target material is more than 20.0 ppm by mass, K contained in the gate electrode also becomes more than about 20.0 ppm by mass. For this reason, a change in threshold voltage of a semiconductor occurs, switching is difficult within a predetermined voltage range, and the TFT characteristics become unstable. This is presumed to be because K contained in the gate electrode is diffused into a gate insulating film or a polysilicon film due to a diffusion phenomenon.

Thus, in the present invention, K contained in the target material is set to 20.0 ppm by mass or less. K in the target material of the present invention is preferably set to 18.0 ppm by mass or less, and more preferably 14.0 ppm by mass or less.

Here, Mo powder that is commercially available as a raw material powder used for production of the target material contains K of about 40.0 ppm by mass, and even when an attempt is made to pressure-sinter the Mo powder in a sealed space of a hot isostatic press to obtain the target material, it is difficult to reduce K. Therefore, to obtain the target material of the present invention, K is preferably reduced to 20.0 ppm by mass or less in a state of the raw material powder in advance. Here, as means for reducing K in the raw material powder, for instance, a two-stage reduction method is preferably applied. Thereby, in addition to an effect of reducing K, volatilization of MoO₃ that is a raw material of the Mo powder can be avoided.

As another means for reducing K in the raw material powder, a decompression deaeration method may be applied before the raw material powder is filled in a container and is pressure-sintered, that is, in the state of the raw material powder.

Deaeration is preferably performed under conditions of decompression deaeration, within a range of 600 to 1000° C. which is a heating temperature under reduced pressure that is lower than atmospheric pressure (101.3 kPa).

K in the target material of the present invention is set to 20.0 ppm by mass or less. Thereby, when the gate electrode is formed, the contamination of the inside of the chamber of the sputtering system is inhibited, so that the contamination of the obtainable gate electrode can be prevented and the stable TFT characteristics can be secured. Meanwhile, excessively reducing K in the target material leads to a rise in production costs. Even when the two-stage reduction method or the decompression deaeration method is adopted, it is practically difficult to make K in the raw material powder lower than 0.4 ppm by mass. For this reason, in the present invention, K contained in the target material is set to 0.4 ppm by mass or less. K in the target material of the present invention is preferably set to 2.5 ppm by mass or more, and more preferably 3.0 ppm by mass or more.

The target material of the present invention comprises a Mo alloy that contains, in Mo, a total of 50 atom % or less of one or two or more elements M selected from among the group consisting of W, Nb, Ta, Ni, Ti and Cr, and the remainder comprising unavoidable impurities. When considering an excellent point in both ease of a process of forming the gate electrode and performance as the gate electrode, a MoW alloy in which W as the element M is 10 to 50 atom % is preferably used.

Hereinafter, an example of a process of producing the target material of the present invention will be described.

In the present invention, the target material can be obtained by pressure sintering the aforementioned raw material powder. For example, a hot isostatic press or a hot press can be applied to the pressure-sintering, and the pressure-sintering is preferably performed on conditions of a sintering temperature of 800 to 2000° C., a pressure of 10 to 200 MPa, and a time of 1 to 20 hours.

Selection from these conditions is dependent on a composition, a size, etc. of a target material to be obtained, pressure-sintering equipment, and so on. For example, a low-temperature high-pressure condition is easily applied to the hot isostatic press, and a high-temperature low-pressure condition is easily applied to the hot press. In the present invention, the hot isostatic press capable of obtaining a large target material is preferably used.

By setting the sintering temperature to 800° C. or higher, it is possible to accelerate the sintering and obtain a dense target material. On the other hand, by setting the sintering temperature to 2000° C. or lower, it is possible to inhibit crystal growth of a sintered compact and obtain a uniform and fine structure.

By setting the applied pressure to 10 MPa or higher, it is possible to accelerate the sintering and obtain a dense target material. On the other hand, by setting the applied pressure to 200 MPa or lower, a general-purpose pressure-sintering system can be used.

By setting the sintering time to 1 hour or more, it is possible to accelerate the sintering and obtain a dense target material. On the other hand, by setting the sintering time to 20 hours or less, a dense target material can be obtained without impeding production efficiency.

A relative density in the present invention refers to a value that is 100 times a value obtained by dividing a bulk density measured by an Archimedes method by a theoretical density obtained as a weighted average of element simple substances calculated by a mass ratio obtained from a composition ratio of the target material of the present invention.

When the relative density of the target material is lower than 95.0%, voids in the target material increase, and generation of a nodule responsible for abnormal electrical discharge during a sputtering process with these voids as a base point is easily caused. For this reason, the relative density of the target material of the present invention is preferably higher than or equal to 95.0%. The relative density is more preferably higher than or equal to 99.0%.

### EXAMPLES

First, Mo powder and W powder were mixed to be 85% Mo and 15% W by atom by a cross rotary mixer to prepare a mixed powder. At this time, the mixed powder in which a K content was 5.0 ppm by mass that was a value measured by atomic absorption spectrometry was used as a target material in Example 1. The mixed powder in which contents of K were 6.0 ppm by mass, 7.0 ppm by mass, 8.0 ppm by mass, 9.0 ppm by mass, and 14.0 ppm by mass was used as target materials in Examples 2 to 6. On the other hand, the mixed powder in which a K content was 20.0 ppm by mass was used as a target material in Comparative Example.

Next, each of the prepared mixed powders was filled in a pressurized container made of mild steel, and the pressurized container was sealed by welding an upper lid having a deaeration port.

Next, each of the pressurized containers was deaerated in a vacuum at a temperature of 450° C., and a sintered compact that was not subjected to hot isostatic pressing on conditions of a temperature of 1250° C., a pressure of 145 MPa, and a time of 5 hours and served as a material for the target material was obtained.

A sample for component analysis and relative density measurement was collected from each of the obtained sintered compacts by machining, and a K content and a relative density were measured. Here, the relative density was a value that was 100 times a value obtained by dividing a bulk density measured by an Archimedes method by a theoretical density obtained as a weighted average of element simple substances calculated by a mass ratio obtained from a composition ratio of a MoW alloy target material.

The K content in the sintered compact was measured by glow discharge mass spectrometry (available from V.G. Scientific Company (currently Thermo Fisher Scientific Company), model number: VG9000).

Each of the obtained sintered compacts was machined to a diameter of 180 mm and a thickness 7 mm, and a target material was made. Each of the target materials was disposed in a chamber of a DC magnetron sputter apparatus (model: C3010) available from Canon Aneruva Company, and a MoW alloy thin film having a thickness of 400 nm was formed on a glass substrate on conditions of Ar gas pressure of 0.5 Pa and input power of 500 W. The K content in each of the obtained MoW alloy thin films was measured by IMS-4F available from Cameca Company. The K content in the MoW alloy thin film adopted an analytical value between 50 and 250 nm that was a depth from a surface of the MoW alloy thin film in order to obtain a stable value without being affected by the surface of the MoW alloy thin film and the glass substrate.

TABLE 1

| | | K content of | | | |
|---|---|---|---|---|---|
| | Composition | target | K content of | | |
| | of target | material | alloy thin | Relative | |
| | material | (ppm by | film (×10¹⁸ | density | |
| | (atom %) | mass) | Atoms/cm³) | (%) | Remarks |
| 1 | 85Mo—15W | 5.0 | 3.0 | 99.8 | exemplary |
| | | | | | example 1 of |
| | | | | | the present |
| | | | | | invention |
| 2 | 85Mo—15W | 6.0 | 3.0 | 99.6 | exemplary |
| | | | | | example 2 of |
| | | | | | the present |
| | | | | | invention |
| 3 | 85Mo—15W | 7.0 | 2.6 | 99.7 | exemplary |
| | | | | | example 3 of |
| | | | | | the present |
| | | | | | invention |
| 4 | 85Mo—15W | 8.0 | 3.0 | 99.7 | exemplary |
| | | | | | example 4 of |
| | | | | | the present |
| | | | | | invention |
| 5 | 85Mo—15W | 9.0 | 3.2 | 99.8 | exemplary |
| | | | | | example 5 of |
| | | | | | the present |
| | | | | | invention |
| 6 | 85Mo—15W | 14.0 | 5.0 | 99.7 | exemplary |
| | | | | | example 6 of |
| | | | | | the present |
| | | | | | invention |
| 7 | 85Mo—15W | 21.0 | 7.1 | 99.7 | Comparative |
| | | | | | Example |

The results of Table 1 show that all the K contents of the target materials of exemplary examples of the present invention were lower than or equal to 20.0 ppm by mass. A sputtering test was performed using the target materials in exemplary examples of the present invention. As a result, it could be confirmed that there was no contamination caused by K the inside of the chamber and sputtering could be done well. It is found from the results of Table 1 that, as the K content of the target material increases, the K content in the alloy thin film increases as well.

On the other hand, the K content of the target material of Comparative Example outside of the scope of the present invention was 21.0 ppm by mass. When the sputtering test was performed using this target material and the inside of the chamber was cleaned, it was confirmed that K was trapped, and the inside of the chamber was contaminated.

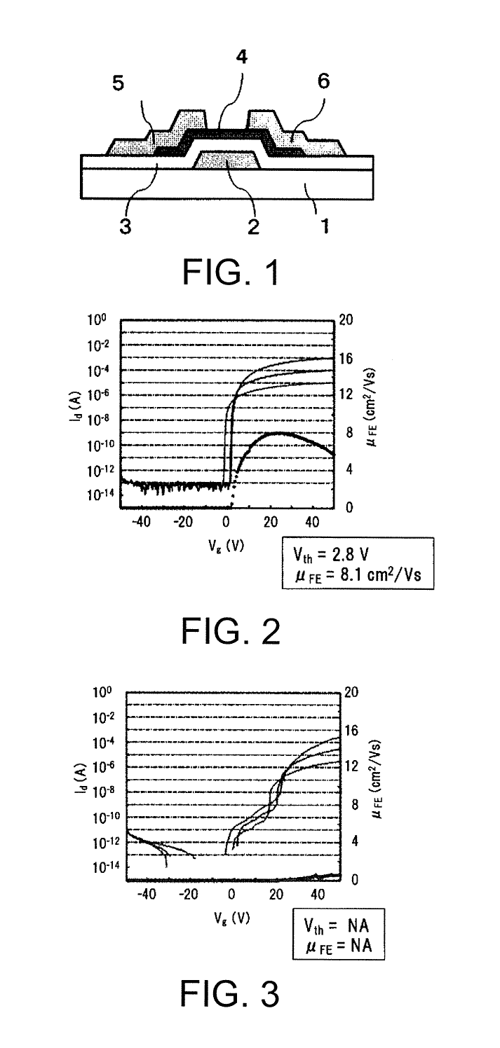

Next, to confirm an influence on TFT characteristics due to K, a simplified TFT shown in FIG. 1 was made, and evaluation was performed.

First, a metal thin film of Mo—W serving as a gate electrode 2 was formed on the glass substrate 1 by the target material of exemplary example 4 of the present invention. Afterward, a mask of a gate pattern was formed by a photoresist. The metal thin film was etched via this mask, and the gate electrode 2 having a thickness of 70 nm was formed.

Then, a SiO₂ film serving as a gate insulating film 3 was formed to a thickness of 100 nm all over. A channel layer 4 that was formed of ZTO (Zn:Sn=7:3) and had a thickness of 30 nm was formed by sputtering.

Next, a photoresist layer serving as a channel pattern later was formed on the channel layer 4. Here, to process a channel region, a channel pattern was printed, exposed, and developed on the photoresist layer, and a mask was formed. The photoresist layer was etched using this mask, and the channel region was formed.

Further, a metal thin film of Mo serving as a source electrode 5 and a drain electrode 6 was formed to a thickness of 140 nm. The metal thin film was etched using a photoresist as a mask, and the source electrode 5 and the drain electrode 6 were formed. These electrodes were covered with a protective film, and the simplified TFT was made.

A simplified TFT in which a gate electrode was formed was also made using the target material of Comparative Example according to the same method as the above.

Evaluation of TFT current-voltage characteristics was performed using each of the simplified TFTs that were made. A result of the evaluation of the characteristics of the simplified TFT in which the gate electrode was formed by the target material of exemplary example 4 of the present invention is shown in FIG. 2. The transverse axis of FIG. 2 is a gate voltage V_{g} [V], and the longitudinal axis is a drain current I_{d} [A]. Three graphs from above are graphs in which drain voltages V_{d} [V] are 0.1 V, 1 V, and 10 V in turn. The lowermost graph is a graph that indicates mobility FE [cm²/Vₛ] of a carrier.

As is apparent from FIG. 2, it was confirmed that the simplified TFT in which the gate electrode was formed by the target material of the present invention is a TFT in which a rise in drain current could be confirmed and stability of a threshold voltage Vₜₕ [V] was secured.

On the other hand, a result of the evaluation of the characteristics of the simplified TFT in which the gate electrode was formed by the target material of Comparative Example is shown in FIG. 3. As is apparent from FIG. 3, in the simplified TFT in which the gate electrode was formed by the target material of Comparative Example, threshold voltage Vₜₕ [V] could not be measured.

### REFERENCE SIGNS LIST

1 Glass substrate
2 Gate electrode
3 Gate insulating film
4 Channel layer
5 Source electrode
6 Drain electrode

1. A target material containing a total of 50 atom % or less of one or two or more elements M selected from the group consisting of W, Nb, Ta, Ni, Ti and Cr, with the remainder comprising Mo and unavoidable impurities, wherein a content of K, which is one of the unavoidable impurities, is 0.4 to 20.0 ppm by mass.

2. The target material according to claim 1, wherein the element M is W, a content of W is 10 to 50 atom %.
